(19) United States
(12) Patent Application Publication
(10) Pub. No.: US 2010/0170561 A1
(43) Pub. Date: Jul. 8, 2010

(54) SOLAR CELL MODULE AND SURFACE LAYER THEREOF

(75) Inventors: Cheng-Yu Peng, Taoyuan County (TW); Ray-Chien Lai, Taoyuan County (TW); Fang-Yao Yeh, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/645,463

(22) Filed: Dec. 22, 2009

(30) Foreign Application Priority Data
Jan. 8, 2009 (TW) 98100494

(51) Int. Cl. H01L 31/052

(52) U.S. Cl. 136/246

(57) ABSTRACT

A surface layer of a solar cell module is provided for being added onto a surface of the solar cell module. The surface layer is a liquid having a predetermined height and a refractive index from 1 to 1.55 for increasing light transmission and/or a thermal resistivity of the surface layer is less than that of the glass to improve heat dissipation of the solar cell module. The surface layer of the solar cell further includes a storage buffer apparatus to keep the predetermined height of the surface layer with/without texture from wave generators for the improvement in light transmission and heat dissipation.

### CROSS-REFERENCE TO RELATED APPLICATION

This application claims the priority benefit of Taiwan application serial no. 98100494, filed Jan. 8, 2009. The entirety of the above-mentioned patent application is hereby incorporated by reference herein and made a part of specification.

### BACKGROUND OF THE INVENTION

1. Field of the Invention

The present invention relates to a solar cell module with high light transmission and good heat dissipation, and a surface layer of the solar cell module with/without texture from wave generators.

2. Description of Related Art

FIG. 1 shows a package structure of a typical solar cell module which consists of air 100/glass 102/polymer material (EVA, PVB) 104/solar cell 106/high reflective back plate 108/air 100. Such a solar cell module that is formed by the glass and solar cell bonded with the polymer material generally in a sandwiched manner still suffers from considerable package loss, such as, optical reflective loss, thus reducing the power generation.

The optical loss of the solar cell module largely comes from, for example, the reflective loss between the air and the glass at the module surface, the reflective loss at the interface between various package materials of the solar cell module, the loss caused by temperature effect due to solarization of the module, and the loss caused by the foul or shield of the module.

In order to address these losses, most current solutions are on the designs of high efficiency solar cell module package materials and structures for increasing the power of the module. For example, one proposal is to use a solar cell with an anti-reflective surface. There are also some relevant patents issued recently. For example, U.S. Pat. No. 6,101,946 proposes to manufacture a textured glass surface to increase light transmission; U.S. patent application publication No. 2008/0000517 A1 proposes a high reflective back plate with an embossed surface; and U.S. Pat. No. 5,994,641 proposes that a toothed structure facing the solar light is disposed between solar cells of the cell array.

Since the current technologies are largely focused on the module material development and manufacture, companies now are putting their efforts on high light transmission elements accordingly, for example, the glass surface texture structure technology or the solar cell anti-reflective layer technology. Another focus is on the high reflection technology of the back plate. However, there is not a module structure which has both high light transmission and good heat dissipation to effectively increase large-area light transmission and reduce the module temperature to thereby increase the efficiency of the module.

### SUMMARY OF THE INVENTION

Accordingly, the present invention is directed to a surface layer of a solar cell module which can improve light transmission and heat dissipation.

The present invention is also directed to a solar cell module which has an additive storage buffer apparatus to keep the surface layer to a predetermined height, thereby improving light transmission of the solar cell module as well as heat dissipation of the module.

The present invention provides a surface layer of a solar cell module adapted to be added onto a surface of the solar cell module. The surface layer is a liquid having a predetermined height, and a refractive index of between 1 and 1.55 and/or a thermal resistivity smaller than that of a glass.

The present invention also provides a solar cell module comprising a solar panel and a surface layer. The solar panel comprises a substrate at a surface of the solar panel, and the surface layer is positioned on the substrate. The surface layer is a liquid having a predetermined height. The liquid also has a refractive index of between 1 and 1.55 for improving light transmission and/or a thermal resistivity smaller than that of the substrate for improving heat dissipation of the solar cell module.

In view of the foregoing, in the present invention, the surface layer of the solar cell module can form a simple module texture structure, the waves are easy to generate, and the power generation can be increased.

In order to make the aforementioned and other features and advantages of the present invention more comprehensible, embodiments accompanied with figures are described in detail below.

### BRIEF DESCRIPTION OF THE DRAWINGS

FIG. 1 shows a package structure of a typical solar cell module

FIG. 2 illustrates a surface layer of a solar cell PV module according to one embodiment of the present invention.

FIG. 3 illustrates a surface layer of a solar cell module according to another embodiment of the present invention.

FIG. 4 illustrates a surface layer of a solar cell module according to yet another embodiment of the present invention

FIGS. 5A, 5B, 5C and 5D each illustrate a solar cell module according to one embodiment of the present invention.

FIGS. 6A and 6B each illustrate a solar cell module according to another embodiment of the present invention.

FIG. 7 shows current-voltage (I-V) curves derived from experiments conducted on the conventional solar cell module and the solar cell module of the present invention, respectively.

### DESCRIPTION OF THE EMBODIMENTS

FIG. 2 illustrates a surface layer of a solar cell (PV) module according to one embodiment of the present invention.

Referring to FIG. 2, a surface layer 204 is formed on a surface 202 of a solar cell module 200. The surface layer 204 is a liquid having a predetermined height h and with a refractive index of between 1 and 1.55 and/or a thermal resistivity smaller than that of a glass. The liquid may, for example, be water or alcohol. In the case of water, the predetermined height h of the surface layer 204 is less than about 5 cm, and is preferably several of millimeters (mm). The structure of the solar cell module 200 is not shown in detail in FIG. 2. However, it will be appreciated that the surface layer 204 illustrated herein can be utilized in a wide variety of solar cell modules, such as, a silicon solar cell module, a thin film solar cell module, a compound solar cell module, a dye-sensitized solar cell module, a nanometer solar cell module, an organic solar cell module, a solar cell module system, etc. In addition, the surface of the solar cell module 200 can be a horizontal surface or an inclined surface.

In the present embodiment, the liquid structure (i.e., surface layer 204) is added onto the surface of the solar cell module 200 thereby producing an anti-reflection effect. This not only increases an output power and a heat dissipation performance of the solar cell module 200, but also makes the solar cell module anti-fouling and easy to clean.

Moreover, in FIG. 2, there is an additive storage buffer apparatus 206 to keep the predetermined height h of the surface layer 204. For example, the storage buffer apparatus 206 includes a storage device, a circulating system or a backside storage buffer.

FIG. 3 illustrates a surface layer of a solar cell module according to another embodiment of the present invention, in which reference numerals that are the same as in FIG. 2 refer to the same elements.

Referring to FIG. 3, a surface layer 302 with waves 300 may be formed onto the surface 202 of the solar cell module 200. Here, the waves can be generated in a passive manner or in an active manner. For example, the waves 300 of FIG. 3 are generated in a passive manner as a result of a liquid flow path resistance. In other words, a flow resistance substrate (not shown) with a raised texture surface 202 can be configured to generate the waves 300, when the surface layer 302 flowing along the raised texture surface 202. In addition, the waves 300 can also be generated as a result of the characteristic of the liquid itself, such as by escape of gas bubbles from a gas-liquid.

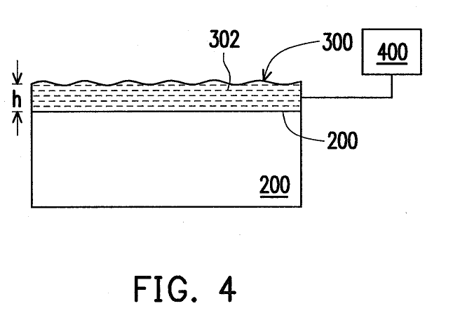

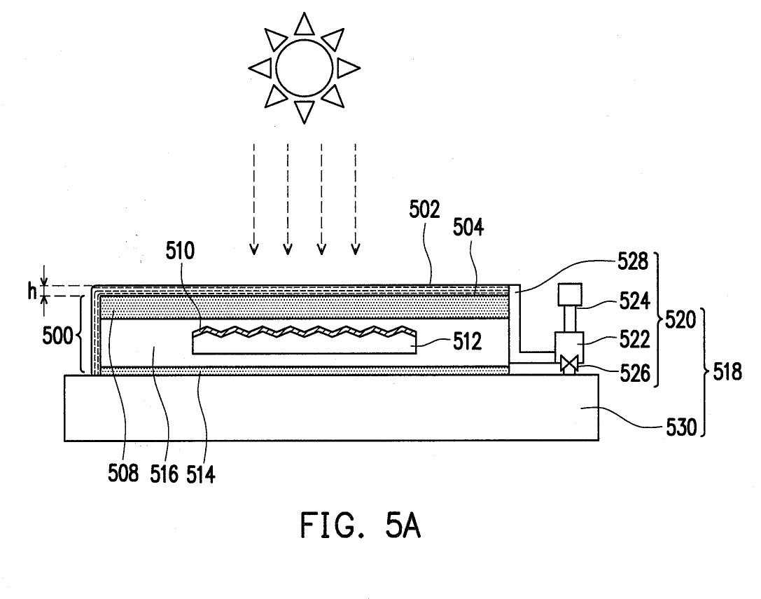

FIG. 4 illustrates a surface layer of a solar cell module according to another embodiment of the present invention, in which reference numerals that are the same as in FIG. 3 refer to the same elements.

Referring to FIG. 4, the surface 202 of the solar cell module 200 is a planar surface and the waves 300 of the surface layer 302 can be generated by an external force. In other words, an extra wave generator 400 can be employed as the storage buffer apparatus (e.g. 206 on FIG. 3) to change intensity, frequency or form of the waves 300 of the surface layer 302. In this embodiment, the wave generator 400 includes pump switch or movable gate, for example.

Since the surface layer 302 itself can provide anti-reflection at the glass surface and with the additional light guide design of the waves 300, the light transmission rate can further be increased, and the condition of total reflection can be satisfied to achieve light trapping in the module. Therefore, the present embodiment can provide the anti-reflection and high light transmission of the solar cell module 200 as well as the light trapping of the typical solar cell and back plate.

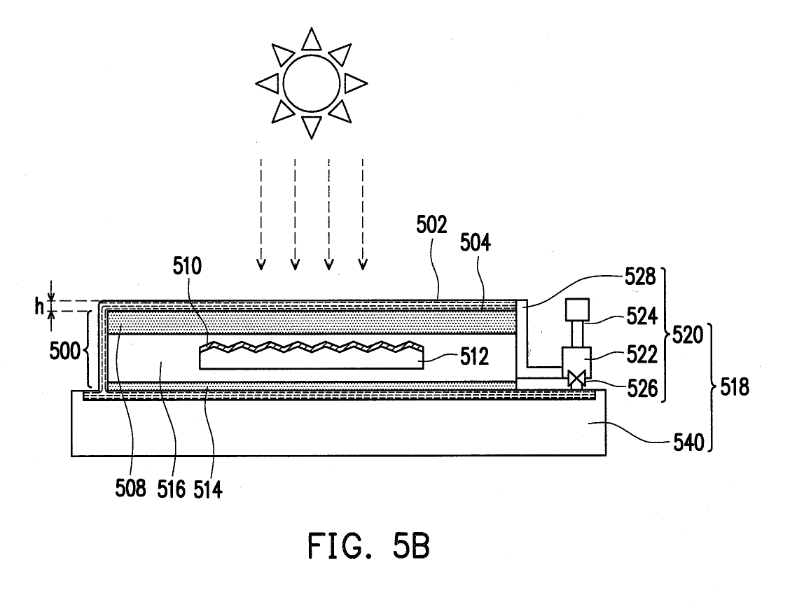

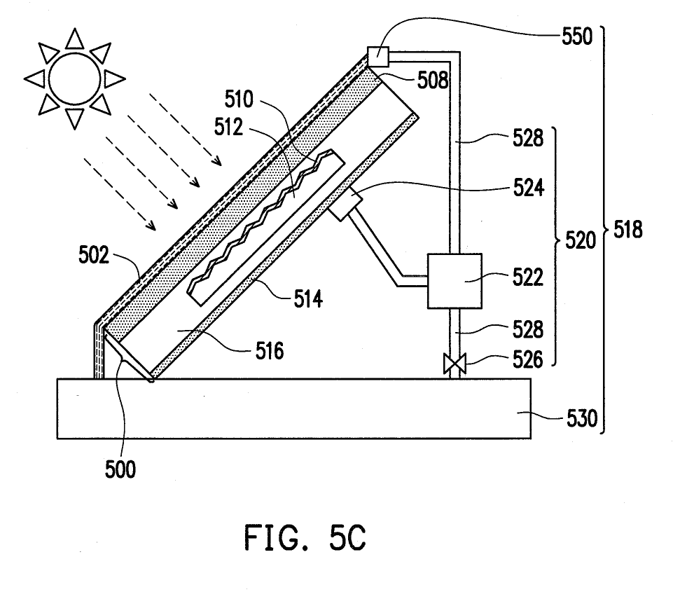

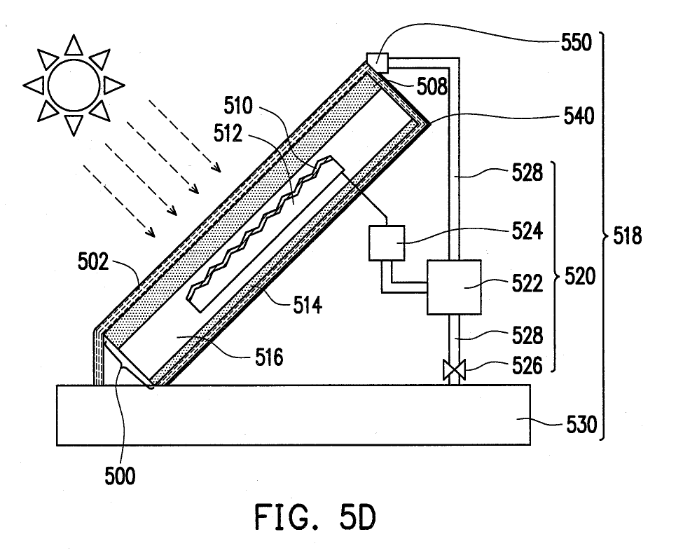

FIG. 5A illustrates a solar cell module according to one embodiment of the present invention.

Referring to FIG. 5A, the solar cell module of the present embodiment includes a solar panel 500 and a surface layer 502. The solar panel 500 includes a substrate 508 at a surface 504 of the solar panel 500. The surface layer 502 is a liquid having a predetermined height h and a refractive index of between 1 and 1.55 (e.g., water or alcohol) and/or a thermal resistivity smaller than that of the substrate 508. In the present embodiment, the surface layer 502 is water having the height h less than about 5 cm. The solar panel 500 includes, for example, a glass substrate with a planar surface. The solar cell module of the present embodiment can be a wide variety of types of solar cell module, such as, a silicon solar cell module, a thin film solar cell module, a compound solar cell module, a dye-sensitized solar cell module, a nanometer solar cell module, an organic solar cell module, a solar cell module system, etc. As shown in the drawing, the solar panel 500 includes the substrate 508, a solar cell 512 with an anti-reflective surface 510, a highly reflective back plate 514, and a polymer material 516. Besides, the solar panel 500 may be coupled to a storage buffer apparatus 518 integrated with the solar cell module (e.g., by combining the designs of a frame, a surface structure, a module side, a junction box, a back plate or the like) such that the height h of the liquid of the surface layer 502 can be kept.

Referring to FIG. 5A, the storage buffer apparatus 518 can be constructed in any manner to form a static surface layer 502 or a flowing surface layer 502. For example, the storage buffer apparatus 518 includes a circulating system 520 for circulating the liquid on the substrate 508 and a storage device 530 for buffering or supplying the flowing liquid. The circulating system 520, for example, includes a circulator 522 for circulating the liquid, a power supply 524, a liquid valve 526 for exhausting or supplying the liquid, a liquid path 528 for maintaining static or circulating or balance of the surface layer 502. The frame of the solar cell module can also be used as the storage device 530. In addition, the power supply 524 may be an external power supply as illustrated herein and, alternatively, the power outputted from the solar panel 500 can be extracted for use in lieu of the external power supply.

Experiments conducted on the solar cell module of FIG. 5A show that the maximum power Pₘₚ can be increased by 2.31% if the surface layer 502 is water with the height h of between 3 mm and 5 mm, and Pₘₚ can be increased by 3.15% if the surface layer 502 is alcohol with the height h of between 3 mm and 5 mm.

FIG. 5B is an alternative to the solar cell module of FIG. 5A, in which reference numerals that are the same as in FIG. 5A refer to the same elements. In FIG. 5B, the storage buffer apparatus 518 is a backside storage buffer 540 disposed under the highly reflective back plate 514 of the solar panel 500 for heat radiating and buffering or supplying the flowing liquid. The frame of the solar cell module can also be used as the backside storage buffer 540 for maintaining the height h of static surface layer 502.

FIG. 5C is an alternative to the solar cell module of FIG. 5A, in which reference numerals that are the same as in FIG. 5A refer to the same elements. In FIG. 5C, the solar panel 500 is inclinedly positioned and the storage buffer apparatus 518 may further include a wave generator 550 for generating a liquid flow (i.e. the surface layer 502). For example, the wave generator 550 may be a pump switch or movable gate so as to change intensity, frequency or form of waves of the surface layer 502. It should be understood that the solar cell module of the present invention should not be limited to the particular embodiments described herein.

FIG. 5D is another example of the solar cell module of FIG. 5A, in which reference numerals that are the same as in FIG. 5A refer to the same elements. In FIG. 5D, the solar panel 500 is inclinedly positioned and the storage buffer apparatus 518 includes the circulating system 520, the storage device 530 and the wave generator 550, and further plus the backside storage buffer 540. Therefore, the liquid flow (i.e. the surface layer 502) in the backside storage buffer 540 can radiate the heat of the highly reflective back plate 514a. The frame of the solar cell module can also be used as the backside storage buffer 540 in FIG. 5D.

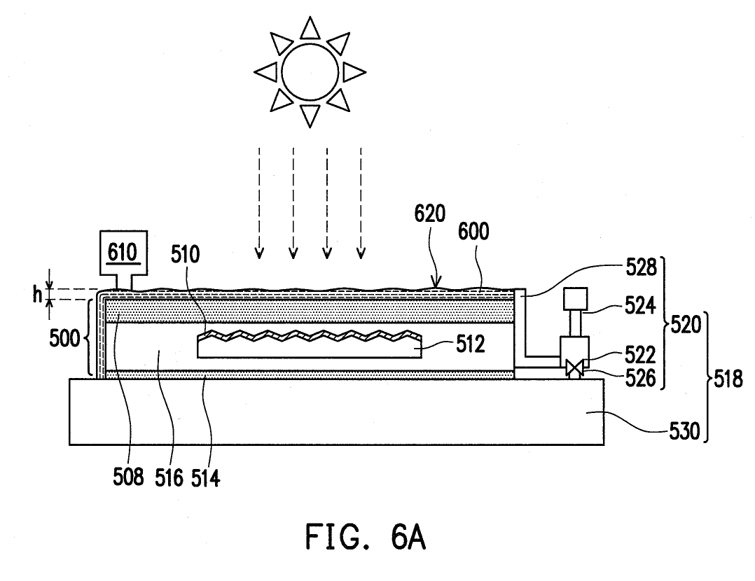

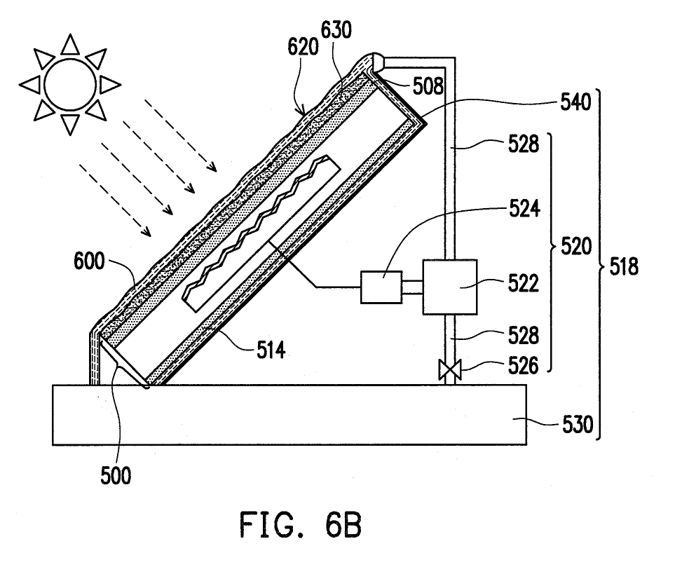

FIG. 6A illustrates a solar cell module according to another embodiment of the present embodiment, in which reference numerals that are the same as in FIG. 5A refer to the same elements.

Referring to FIG. 6A, the solar cell module of the present embodiment includes the solar panel 500 and a surface layer 600. The surface layer 600 is a liquid with a refractive index of between 1 and 1.55 (e.g., water or alcohol) or a thermal resistivity smaller than that of the substrate 508 for dissipating heat of the module. In the case of water, the surface layer 600 has a predetermined height h less than about 5 cm. In the present embodiment, the substrate 508 and the solar cell 512, high reflective back plate 514 and polymer material 516 of the solar panel 500 can be constructed as in known solar cell modules. In addition, as in FIG. 5A, the structure of the present embodiment may be coupled to the storage buffer apparatus 518 integrated with the solar cell module, and the storage buffer apparatus 518 may further include a circulation system 520 and a wave generator 610 for generating waves 620 over the substrate 508 and further changing intensity, frequency or form of waves 620, wherein the wave generator 610 may be, for example, a pump switch or movable gate. If the substrate 508 includes a flow resistance substrate (e.g., the surface 202 in FIG. 3) with a raised texture surface, it can cause the liquid of the surface layer 600 to generate waves 620. As shown in FIG. 6A, the surface layer 600 has a simple structure, the waves 620 are easy to generate and the output power of the module is increased when compared with the conventional solar cell module.

Experiments conducted on the solar cell module of FIG. 6A show that the maximum power Pₘₚ can be increased by 2.67% if the surface layer 600 is water with a height of between 3 mm and 5 mm and the size of the storage device 530 of the storage buffer apparatus 518 is 15 cm×15 cm, and Pₘₚ can be increased by 3.85% if the surface layer 600 is alcohol with a height of between 3 mm and 5 mm.

FIG. 6B is an alternative to the solar cell module of FIG. 5A, in which reference numerals that are the same as in FIG. 6A refer to the same elements. In FIG. 6B, the solar panel 500 is inclinedly positioned and the surface of the substrate 508 can be configured to have a structure 630 such that the surface layer 600, when flowing, can generate waves 620 without use of the wave generator. Furthermore, in FIG. 6B, the storage buffer apparatus 518 further includes the backside storage buffer 540 disposed under the highly reflective back plate 514 of the solar panel 500 for heat radiating and buffering or supplying the flowing liquid.

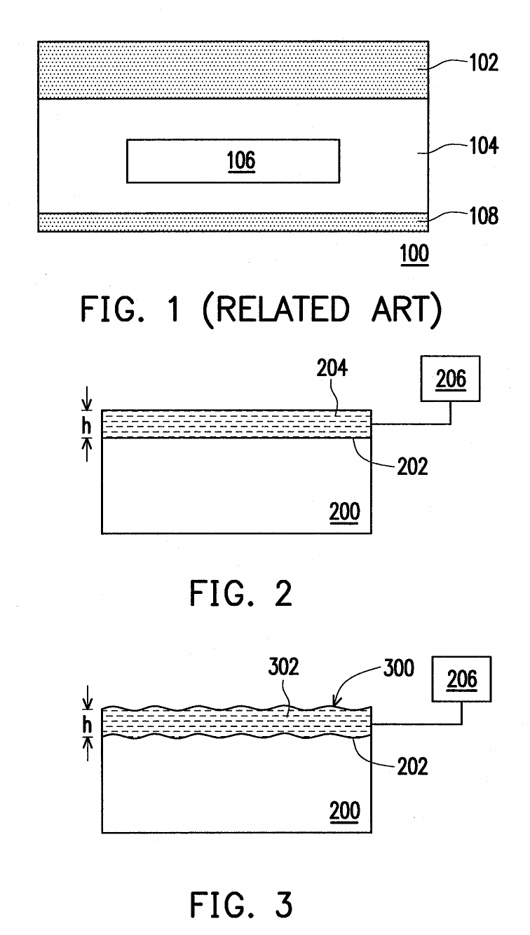

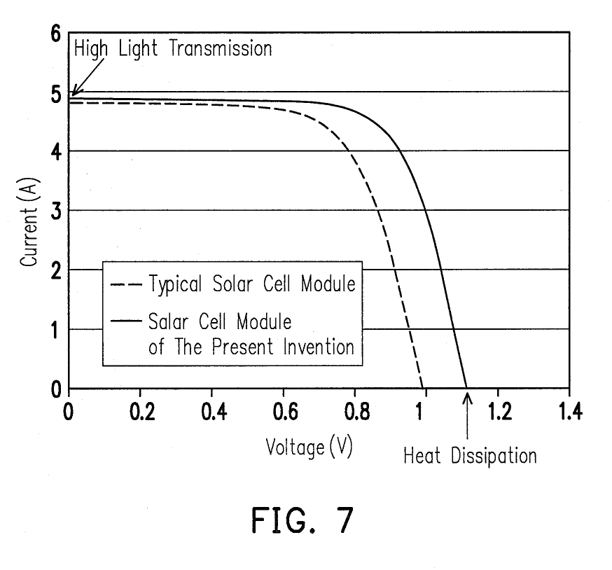

In addition, FIG. 7 shows the heat dissipation performance of the solar cell module of the present invention, which shows current-voltage curves derived from experiments conducted at the module temperature of Celsius 80 degrees on the conventional solar cell module (FIG. 1) and the solar cell module of the present invention (FIG. 6), respectively. It can be seen from FIG. 7 that, at the high temperature of Celsius 80 degrees, the solar cell module of the present invention has a high light transmission rate as well as a 20.85% increase of the maximum power Pₘₚ.

In summary, in the present invention, the surface layer formed from liquid is added to the solar cell module, and the surface layer can be further configured to have waves so as to achieve a textured high light transmitting structure. In addition, the liquid surface layer of the present invention can dissipate heat of the solar cell module. Therefore, in the structure of the present invention, the waves are easy to generate, the module is anti-fouling and easy to clean, and the power and the heat dissipation performance are increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A surface layer of a solar cell module adapted to be added onto a surface of the solar cell module, the surface layer being characterized as being a liquid having a predetermined height, and a refractive index of between 1 and 1.55 and/or a thermal resistivity smaller than that of a glass.

2. The surface layer of a solar cell module according to claim 1, wherein the liquid is water or alcohol.

3. The surface layer of a solar cell module according to claim 1, wherein the predetermined height of the surface layer is several of millimeters.

4. The surface layer of a solar cell module according to claim 1, wherein the surface layer comprises waves.

5. The surface layer of a solar cell module according to claim 4, wherein the waves are generated in a passive manner or in an active manner.

6. The surface layer of a solar cell module according to claim 5, wherein the passive manner is such that the waves are generated using an external force or as a result of a liquid flow path resistance.

7. The surface layer of a solar cell module according to claim 1, wherein the surface layer is kept in the predetermined height by a storage buffer apparatus.

8. The surface layer of a solar cell module according to claim 7, wherein the storage buffer apparatus comprises a storage device, a circulating system, a backside storage buffer or a wave generator.

9. The surface layer of a solar cell module according to claim 1, wherein the solar cell module comprises a silicon solar cell module, a thin film solar cell module, a compound solar cell module, a dye-sensitized solar cell module, a nanometer solar cell module, an organic solar cell module, or a solar cell module system.

10. A solar cell module comprising:
a solar panel comprising a substrate at a surface of the solar panel; and
a surface layer positioned on the substrate, the surface layer being a liquid having a predetermined height and a refractive index of between 1 and 1.55 and/or a thermal resistivity smaller than that of the substrate.

11. The solar cell module according to claim 10, further comprising a storage buffer apparatus for keeping the predetermined height of the surface layer.

12. The solar cell module according to claim 11, wherein the storage buffer apparatus comprises a storage device, a circulating system, a backside storage buffer or a wave generator.

13. The solar cell module according to claim 10, where the liquid is water or alcohol.

14. The solar cell module according to claim 10, wherein the predetermined height of the surface layer is several of millimeters.

15. The solar cell module according to claim 10, wherein the substrate is a flow resistance substrate with a raised texture surface.

16. The solar cell module according to claim 10, wherein the solar cell module comprises a silicon solar cell module, a thin film solar cell module, a compound solar cell module, a dye-sensitized solar cell module, a nanometer solar cell module, an organic solar cell module, or a solar cell module system.
